(19) United States
(12) Patent Application Publication
(10) Pub. No.: US 2012/0074444 A1
(43) Pub. Date: Mar. 29, 2012

(54) LIGHT EMITTING DEVICE AND MANUFACTURING METHOD THEREOF

(75) Inventors: YUE-ZHI CHEN, Hsinchu (TW); CHIA-CHEN CHANG, Hsinchu (TW)

(73) Assignee: ADVANCED OPTOELECTRONIC TECHNOLOGY, INC., Hsinchu Hsien (TW)

(21) Appl. No.: 13/110,005

(22) Filed: May 18, 2011

(30) Foreign Application Priority Data
Sep. 28, 2010 (CN) 201010294962.4

(51) Int. Cl. H01L 33/60

(52) U.S. Cl. 257/98; 438/29; 257/E33.072

(57) ABSTRACT

The disclosure provides a light emitting device comprising a light source and a reflector, having specular ink, surrounding the light source.

### TECHNICAL FIELD

The disclosure relates generally to a light emitting device and a method for manufacturing the device, and more particularly to a semiconductor light emitting device and a method for manufacturing same.

### DESCRIPTION OF THE RELATED ART

Presently, light emitting devices are widely used in lighting, which contain light emitting diode (LED) modules and light emitting diodes. Many light emitting diode modules include a printed circuit board (PCB) for providing electrical power to an LED light source. An insulating paint is applied on the exterior surface of the PCB to prevent short circuits. The insulating paint, usually white, is able to reflect light emitted from the LED light source. However, the reflective efficiency of the insulating paint is limited, having a reflective index of about 70˜80%, which is not cost effective.

Similarly, the white plastic material is also widely used in the light emitting diodes to form a reflective cup or a reflector for reflecting light emitting from the light source. However, the reflective efficiency of the white plastic material is also limited.

### BRIEF DESCRIPTION OF THE DRAWINGS

FIG. 1 is a cross section of a light emitting device in accordance with one embodiment of the disclosure.

FIG. 2 is a cross section of a light emitting device in accordance with another embodiment of the disclosure.

FIG. 3 is a flow chart of a method for manufacturing a light emitting device of the disclosure.

FIG. 4 is a schematic diagram showing different steps of the method in manufacturing the light emitting device of FIG. 3.

### DETAILED DESCRIPTION

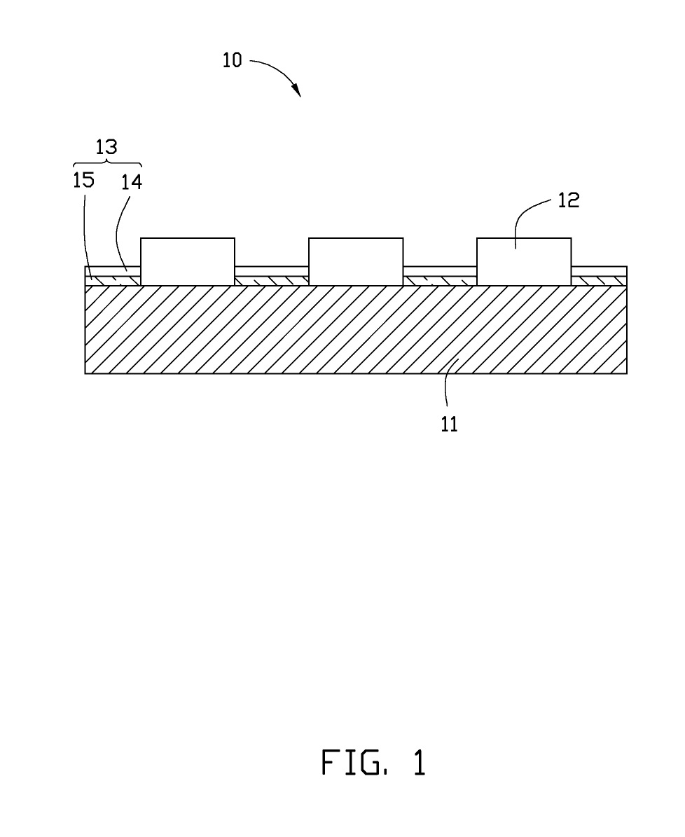

As shown in FIG. 1, the disclosure provides a light emitting module 10 comprising a printed circuit board (PCB) 11, a plurality of light emitting diodes (LEDs) 12 electrically connected to the PCB 11, and a reflector 13. Specifically, the light emitting diodes 12 and the reflector 13 are located on a top surface of the PCB 11, wherein the reflector 13 surrounds the LEDs 12.

The reflector 13 is composed of a transparent substrate 14 and a reflective material 15 applied to the transparent substrate 14 and located between the transparent substrate 14 and the PCB 11. The reflective material 15 comprises specular ink having high reflective index above 95%. Light reflected by the reflector 13 will have nearly its original illumination from the LEDs 12.

The specular ink is insulative, anti-oxidative and solder resistant. Accordingly, after the specular ink is dried, the specular ink is not liable to combine with other materials. That is, the circuitry of the light emitting module 10 including that in the PCB 11 and the LEDs 12 is protected. Moreover, the specular ink is also heat resistant, pressure resistant, and highly adhesive among other properties. Specifically, the specular ink has been determined to not easily deteriorate under temperatures ranging from −40° C. to 100° C. over the course of seven days, and even under high heat of 280° C. for 30 to 60 minutes. The waterproof property of the specular ink is above IPX6, and the specular ink is non-toxic and contains no halogen. Further, the adhesive property of the specular ink is rated at ISO 5B, and so can attach to any soft or solid matter. In the disclosure, the PCB 11 is a plane but can be other shapes. Similarly, the reflective material 15 of the reflector 13 can also be other shapes since it is compliantly adhered on the top surface of the PCB 11.

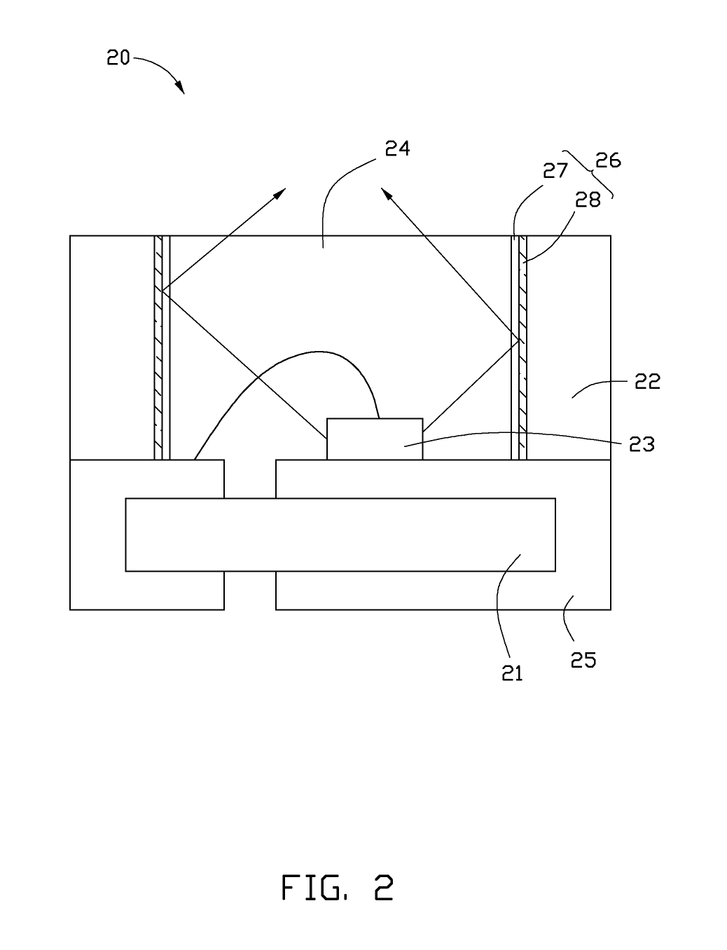

Referring to FIG. 2, the disclosure provides another embodiment of a light emitting diode 20, which comprises a substrate 21 having a reflective cup 22, an encapsulating layer 24 inside the reflective cup 22, an LED chip 23 located on the substrate 21 and covered by the encapsulating layer 24, and a reflector 26 surrounding the LED chip 23.

The substrate 21 comprises a circuit 25 configured for providing power to the LED chip 23. In the disclosure, the substrate 21 is a plane. The reflective cup 22 is located on the substrate 21 for collecting light emitted from the LED chip 23. Alternatively, the reflective cup 22 and the substrate 21 can be formed as an integral unit. The reflector 26 is located on an inner surface of the reflective cup 22, wherein the reflector 26 comprises a transparent substrate 27 and a reflective material 28 applied on the transparent substrate 27. The reflective material 28 is sandwiched between the transparent substrate 27 and the reflective cup 22. The reflective material 28 comprises specular ink as described above.

The LED chip 23 is located on the substrate 21 and is electrically connected to the circuit 25, and is the light source of the LED 20. The LED chip 23 can be electrically connected to the circuit 25 via known means such as wire bonding, eutectic or flip chip. In the disclosure, wire bonding is used.

The encapsulating layer 24 covers the LED chip 23 and the substrate 21, for providing protection and waterproofing. The encapsulating layer 24 is epoxy, silicone or a hybrid thereof, formed by, for example, molding.

Light emitted from the light emitting diode chip 23 and reflected by the reflective material 28 retains approximately 95% of its original illuminating power, whereby the light extraction efficiency of the light emitting diode 20 is enhanced.

In the disclosure, the LED 20 can be assembled in the light emitting module 10 as the light source.

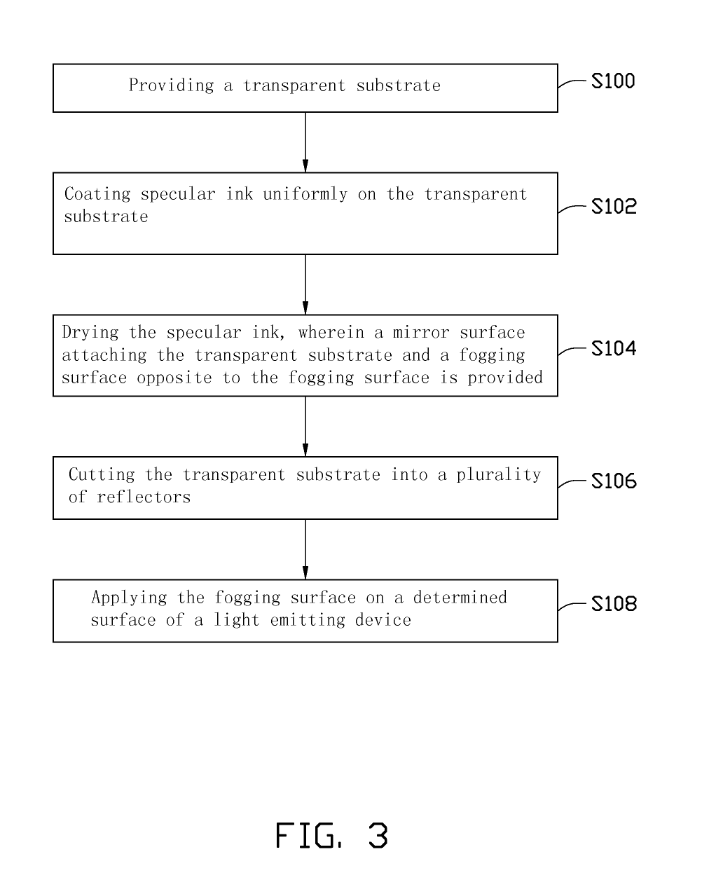

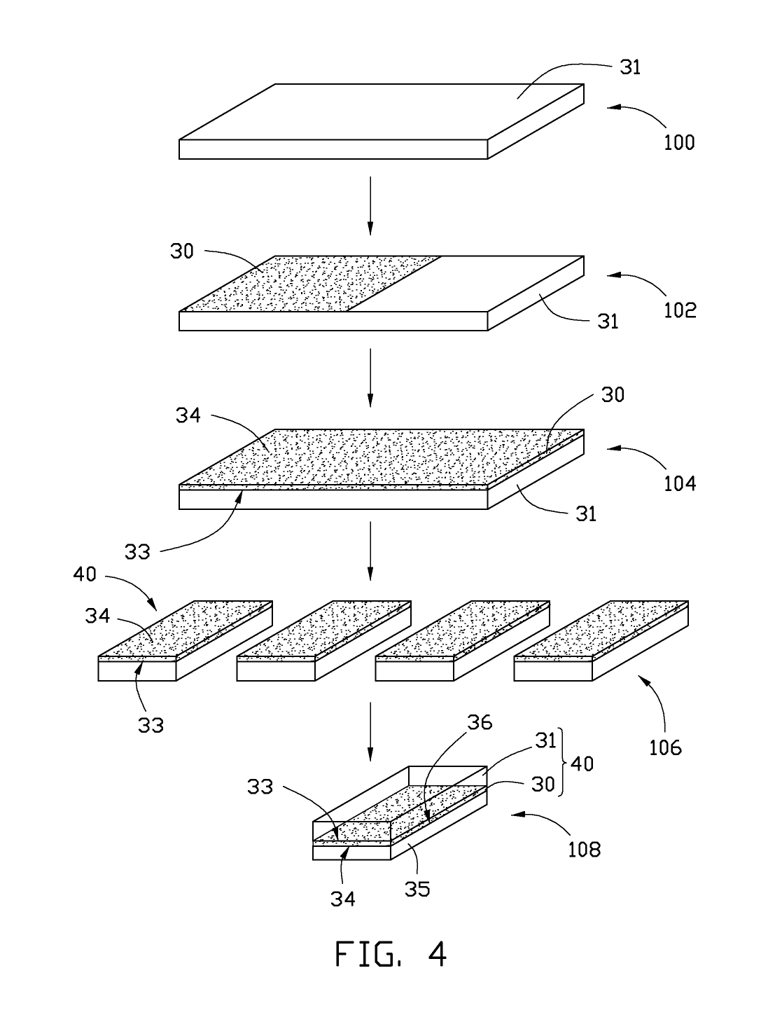

Referring to FIG. 3 and FIG. 4, the disclosure provides a method for manufacturing a light emitting device, comprising the following steps:

In step 100, a transparent substrate 31 is provided. In the disclosure, the transparent substrate 31 can be made of polystyrene (PS), polycarbonate (PC), acrylonitrile butadiene styrene (ABS), polyethylene terephthalate (PET), polyvinyl chloride (PVC) or polymethyl methacrylate (PMMA).

In step 102, specular ink 30 is coated on the transparent substrate 31. Specifically, the specular ink 30 is made by mixing aluminum powder, resin, and suitable diluents. Then, the mixture can be spray-coated or printed on the transparent substrate 31.

In step 104, the specular ink 30 is dried, wherein a mirror surface 33 attaching the transparent substrate 31 and a fogging surface 34 opposite to the mirror surface 33 are provided. In the disclosure, the specular ink 30 can be air dried, oven dried, exposed to UV light, or other known methods.

In step 106, the transparent substrate 31 is cut into a plurality of reflectors 40. The desired shape of the reflector 40 is formed by compressing molding or machining In the disclosure, the desired shape can be a rectangle, a circle or other suitable shape.

In step 108, the reflector 40 is attached on a surface of a light emitting device (not label). In the disclosure, an adhesive (not shown) is applied on the fogging surface 34, and, then, the fogging surface 34 is attached on a determined surface 36 of an object 35 of a light emitting device (not labeled). The object 35 is configured for reflecting light as the PCB 11 or the reflective cup 22, and the determined surface 36 is the top surface of the PCB 11 with the LEDs 12 located thereon (FIG. 1) or the inner surface of the reflective cup 22 (FIG. 2).

It is to be understood, however, that even though multiple characteristics and advantages of the disclosure have been set forth in the foregoing description, together with details of the structure and function of the invention disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting device, comprising:
a light source of solid-state lighting; and
a reflector, surrounding the light source, comprising specular ink, the reflector reflecting light generated by the light source and radiating to the reflector.

2. The light emitting device as claimed in claim 1, wherein the reflector comprising a transparent substrate with the specular ink coating thereon, the light radiating through the transparent substrate to reach and be reflected by the specular ink.

3. The light emitting device as claimed in claim 1, wherein a reflective index of the specular ink is above 95%.

4. The light emitting device as claimed in claim 1, wherein a waterproof property of the specular ink is above IPX6.

5. The light emitting device as claimed in claim 1, wherein the light source is located on a printed circuit board (PCB) and is electrically connected thereto, and the reflector is located on the PCB.

6. The light emitting device as claimed in claim 5, wherein the light source comprising a substrate with a reflective cup having the specular ink, a light emitting diode located on the substrate and an encapsulating layer covering the light emitting diode.

7. A light emitting device, comprising:
a substrate, comprising a reflective cup allocated thereon;
a reflector, coating on an inner surface of the reflective cup, comprising specular ink;
a light emitting diode, located on the substrate and surrounded by the reflective cup; and
an encapsulating layer, covering the light emitting diode and surrounded by the reflective cup.

8. A method for manufacturing a light emitting device, comprising:
providing a transparent substrate;
coating specular ink uniformly on the transparent substrate;
drying the specular ink, wherein a mirror surface attaching the transparent substrate and a fogging surface opposite to the mirror surface are provided;
cutting the transparent substrate into a plurality of reflectors;
providing a light source of solid-state lighting; and
applying the fogging surface on a determined surface of the light source to complete the light emitting device, light generated by the light source and radiating to the specular ink first running through the transparent substrate and then reflected by the specular ink to radiate out of the light emitting device.

9. The method for manufacturing the light emitting device as claimed in claim 8, wherein the specular ink is dried by air dried, oven dried or exposed to UV light.

10. The method for manufacturing the light emitting device as claimed in claim 8, wherein the light source includes a printed circuit board a solid-state lighting element mounted on a surface of the printed circuit board and the determined surface is the surface of the printed circuit board on which the solid-state lighting element is mounted.

11. The method for manufacturing the light emitting device as claimed in claim 8, wherein the light source includes a reflective cup a solid-state lighting element surrounded by the reflective cup and the determined surface is an inner surface of the reflective cup of the light source.

12. The method for manufacturing the light emitting device as claimed in claim 8, wherein the transparent substrate is made of one of following materials: polystyrene (PS), polycarbonate (PC), acrylonitrile butadiene styrene (ABS), polyethylene terephthalate (PET), polyvinyl chloride (PVC) or polymethyl methacrylate (PMMA).

13. The method for manufacturing the light emitting device as claimed in claim 8, wherein the specular ink is made of a mixture of aluminum powder, resin, and diluents.
